(19) United States
(12) Patent Application Publication
(10) Pub. No.: US 2026/0329536 A1
(43) Pub. Date: Oct. 22, 2026

(54) DATA GENERATION DEVICE, BATTERY MONITOR DEVICE, DATA GENERATION METHOD AND NON-TRANSITORY COMPUTER READABLE STORAGE MEDIUM

(71) Applicant: DENSO CORPORATION, Kariya-city (JP)

(72) Inventor: Kazuo MATSUKAWA, Kariya-city (JP)

(21) Appl. No.: 19/559,167

(22) Filed: Mar. 6, 2026

Related U.S. Application Data
(63) Continuation of application No. PCT/JP2024/040159, filed on Nov. 12, 2024.

(30) Foreign Application Priority Data
Dec. 5, 2023 (JP) 2023-205372

(51) Int. Cl. G06F 7/52

(52) U.S. Cl. CPC G06F 7/52

(57) ABSTRACT

A data generation device generates digital data of at least a part of a sine wave or a cosine wave referred to as a predetermined wave. A storage unit is given an initial value. A generation unit generates the digital data by multiplying a stored value of the storage unit by a predetermined coefficient at a predetermined calculation interval that is shorter than a fundamental period of the predetermined wave. The predetermined coefficient is preliminarily determined so as to rotate a unit vector on a two-dimensional complex plane for each predetermined step angle of the predetermined wave.

### CROSS REFERENCE TO RELATED APPLICATION

The present application is a continuation application of International Patent Application No. PCT/JP2024/040159 filed on Nov. 12, 2024, which designated the U.S. and claims the benefit of priority from Japanese Patent Application No. 2023-205372 filed on Dec. 5, 2023. The entire disclosures of all of the above applications are incorporated herein by reference.

### TECHNICAL FIELD

The present disclosure relates to a data generation device, a battery monitor device, a data generation method, and a non-transitory computer readable storage medium.

### BACKGROUND ART

When generating digital data of frequencies in a sine wave and a cosine wave, there have been proposed a method of storing digital data of a sine wave and a cosine wave at a predetermined step angle in a ROM, reading out the digital data, and generating data (for example, according to a conceivable technique), and a method of generating data by calculation (for example, according to another conceivable technique).

### SUMMARY

According to an example, a data generation device generates digital data of at least a part of a sine wave or a cosine wave referred to as a predetermined wave. The data generation device may include: a storage unit to which an initial value is given; and at least one processor with a memory. The at least one processor with the memory is configured to cause the data generation device to execute: generating the digital data by multiplying a stored value of the storage unit by a predetermined coefficient at a predetermined calculation interval that is shorter than a fundamental period of the predetermined wave. The predetermined coefficient is preliminarily determined so as to rotate a unit vector on a two-dimensional complex plane for each predetermined step angle of the predetermined wave.

### BRIEF DESCRIPTION OF THE DRAWINGS

The above-described features and advantages of the present disclosure will become more apparent from the following detailed description with reference to the accompanying drawings. In the drawing:

FIGS. 1A and 1B are an electrical configuration diagram of a data generation device according to a first embodiment and a relationship diagram of frequencies and coefficients;

FIG. 2 is a diagram showing an example of output digital data of a SIN/COS waveform according to the first embodiment;

FIGS. 3A and 3B are an explanatory diagram of the principle of the data generation method in the first to third embodiments, as well as an explanatory diagram of the cumulative error number;

FIG. 4 is an electrical configuration diagram of a data generation device according to a second embodiment;

FIG. 5 is a diagram showing an example of output digital data of a SIN/COS waveform according to the second embodiment;

FIG. 6 is an electrical configuration diagram of a data generation device according to a third embodiment;

FIG. 7 is a diagram showing an example of output digital data of a SIN/COS waveform according to the third embodiment;

FIG. 8 is an electrical configuration diagram of a battery monitor device according to a fourth embodiment;

FIG. 9 is an electrical diagram of the components of a lock-in amplifier according to a fourth embodiment and an explanatory diagram of nodes;

FIG. 10 is a diagram showing the spectrum of each node of the battery monitor device according to the fourth embodiment;

FIG. 11 is an electrical configuration diagram of a battery monitor device according to a fifth embodiment; and

FIG. 12 is a flowchart that outlines the operation of the fifth embodiment.

### DETAILED DESCRIPTION

The method described in the conceivable technique is undesirable because it requires a large amount of memory and increases the circuit size. Furthermore, since the frequencies that can be generated are determined depending on the digital data, the flexibility of the frequencies that can be generated may be reduced, which is undesirable. When generating a low frequency signal, if there is no stored data in the ROM, it may be necessary to interpolate the digital data, which will include harmonics that is undesirable.

The present embodiments have been made in consideration of the above circumstances, and its purpose is to provide a data generation device that can generate digital data of frequencies in a sine wave or a cosine wave as accurately as possible using stored data without the need to interpolate digital data, a battery monitor device using the data generation device, a data generation method, and a data generation program.

One aspect of the present embodiments is directed to a data generation device that generates digital data of at least a portion of a sine wave (SIN) or a cosine wave (COS) (hereinafter referred to as a predetermined wave). One aspect of the present embodiments includes a storage unit that stores an initial value, and a generation unit that generates the digital data by multiplying the stored value of the storage unit by a predetermined coefficient at a predetermined calculation interval that is shorter than the fundamental period of the predetermined wave. The predetermined coefficient is preliminarily determined so as to rotate a unit vector on a two-dimensional complex plane for each predetermined step angle of the predetermined wave.

According to one aspect of the present embodiments, the generation unit generates the digital data by multiplying the stored value of the storage unit by a predetermined coefficient that is preliminarily determined so as to rotate the unit vector on the two-dimensional complex plane for each predetermined step angle of the predetermined wave. Therefore, the digital data can be generated by calculation of the digital data without using the stored data, and the digital data constituting the frequency of a sine wave or a cosine wave can be generated as accurately as possible.

Hereinafter, several embodiments of a data generation device and a battery monitor device will be described with reference to the drawings. In the embodiments described later, the same or similar reference numerals as those in the embodiments described previously will be used to designate the components, and the description thereof will be omitted.

### First Embodiment

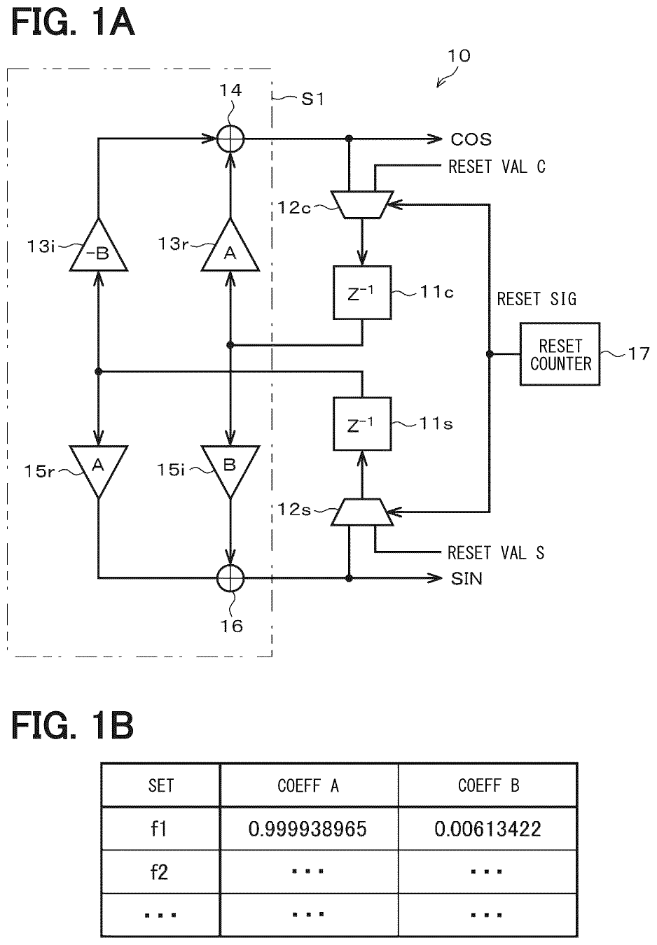

The first embodiment will be described with reference to FIGS. 1A to 3B. The data generation device 10 is configured as a device for generating digital data of a sine wave (SIN) and a cosine wave (COS). In the following description, one period of the digital data of the sine wave and cosine wave generated by the data generation device 10 is defined as a “fundamental period.”

First, the data generation device 10 includes registers 11s and 11c in which initial values are stored. The registers 11s and 11c correspond to a storage unit. The data generation device 10 also includes selectors 12s and 12c, real part coefficient multipliers 13r and 15r, imaginary part coefficient multipliers 13i and 15i, and adders 14 and 16. The real part coefficient multipliers 13r and 15r, the imaginary part coefficient multipliers 13i and 15i, and the adders 14 and 16 constitute a generation unit S1.

The real part coefficient multiplier 13r multiplies the stored value of the register 11c by the real part coefficient A and outputs the result to the adder 14. The imaginary part coefficient multiplier 13i multiplies the stored value in the register 11s by the negative value −B of the imaginary part coefficient and outputs the result to the adder 14. The adder 14 adds the output data of the real part coefficient multiplier 13r and the output digital data of the imaginary part coefficient multiplier 13i, and outputs digital data of a cosine wave (COS). The cosine wave digital data is input to the selector 12c.

The real part coefficient multiplier 15r multiplies the stored value of the register 11s by the real part coefficient A and outputs the result to the adder 16. The imaginary part coefficient multiplier 15i multiplies the stored value in the register 11c by the positive value of the imaginary part coefficient B and outputs the result to the adder 16. The adder 14 adds the output data of the real part coefficient multiplier 15r and the output digital data of the imaginary part coefficient multiplier 15i, and outputs digital data of a sine wave (SIN). The sine wave digital data is input to a selector 12s.

The real part coefficient A of the real part coefficient multipliers 13r and 15r and the imaginary part coefficient B of the imaginary part coefficient multipliers 13i and 15i are predetermined for each frequency f1, f2, and the like. These coefficients A and B may be set in advance in each of the multipliers 13r, 13i, 15r, and 15i, when the output frequency f (for example, f1) is predetermined. Furthermore, when the data generation device 10 is connected to another control circuit (for example, the control unit 30 described below), these coefficients A and B may be configured to be externally settable from the other circuit. It may be desirable to set the coefficients A and B under the condition of an expression of “A\hat{ }2+B\hat{ }2=1”. As the frequencies f1, f2, and the like become smaller, the coefficient A of the real part is set to a larger value, and the coefficient B of the imaginary part is set to a smaller value.

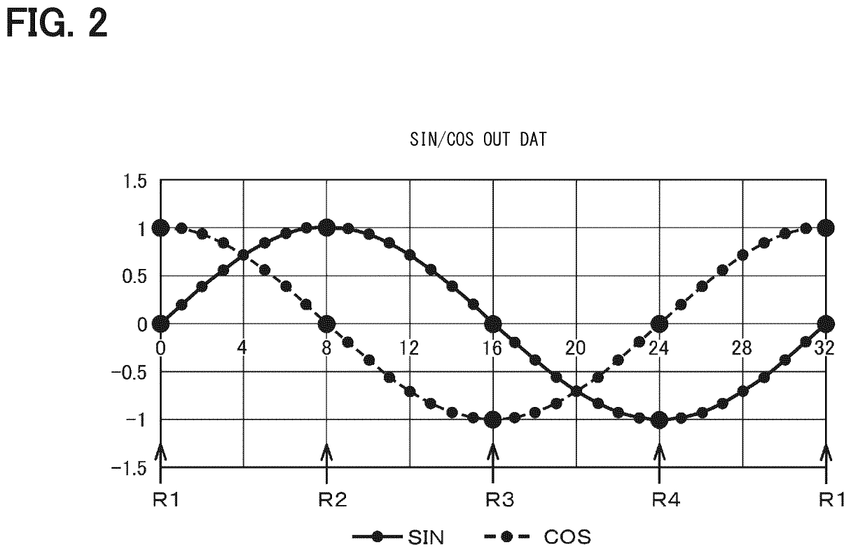

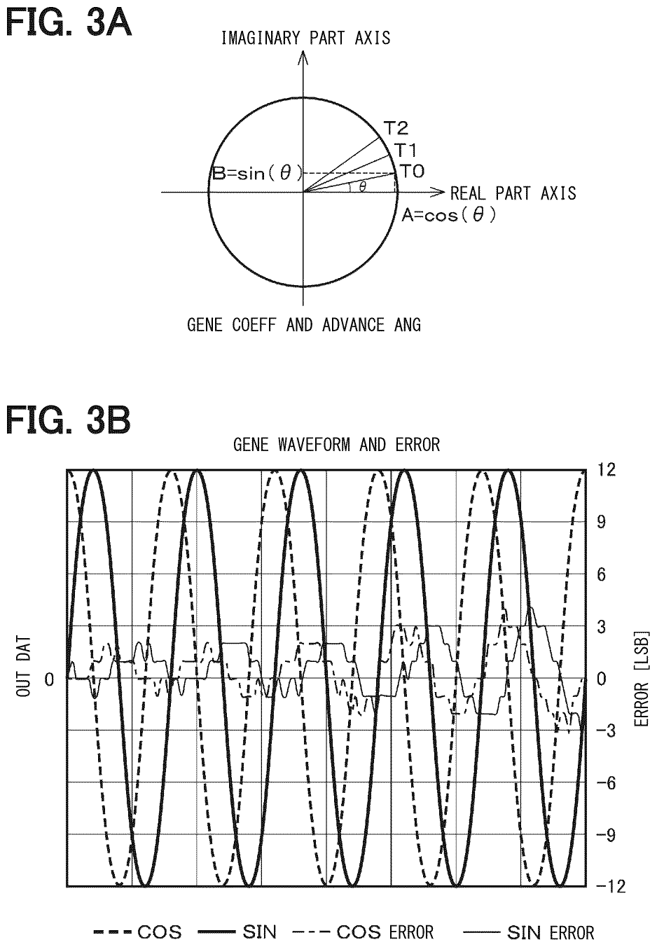

The upper diagram of FIG. 3A shows an explanatory diagram of the principle of the digital data generation method. The generation unit S1 generates the digital data by multiplying the stored values of the registers 11s and 11c by a predetermined coefficient of “(A+jB)” at predetermined calculation intervals (i.e, step periods) T (e.g., T0, T1, T2 and the like in FIG. 3A) that are shorter than the fundamental period of the predetermined wave. The predetermined coefficient of “(A +jB)” is preliminarily determined so as to rotate the unit vector on a two-dimensional complex plane for each predetermined step angle θ. Explaining this feature with reference to the upper diagram of FIG. 3A, the digital data is generated so as to rotate left for each step angle θ on a two-dimensional complex plane. With this configuration, sine wave (SIN) and cosine wave (COS) digital data can be output as shown in FIG. 2.

This can be expressed mathematically as follows. Here, _{Xn} represents a real part, Yₙ represents an imaginary part, A represents a real coefficient, and B represents an imaginary coefficient. Since the rotation is counterclockwise, by multiplying by the coefficient of “(A+jB)” as in expression (1), the real part Xₙ and imaginary part Yₙ of the next step angle θ can be expressed from the current real part Xₙ₋₁ and imaginary part Yₙ₋₁.

Xₙ+jYₙ=(Xₙ₋₁+jYₙ₋₁) (A+jB) =(AXₙ₋₁−BYₙ₋₁)+j(AYₙ₋₁+BXₙ₋₁) (Expression 1)

Furthermore, since the real and imaginary numbers in expression (1) are the same, it can be expressed as expression (2). When the expression (2) is implemented by hardware, it can be configured as shown in the data generation device 10 of FIG. 1B.

Xₙ=AXₙ₋₁−BYₙ₋₁

Yₙ=AYₙ₋₁+BXₙ₋₁ (Expression 2)

Since the coefficients A and B are set by the digital data, there is a limit to the number of bits. furthermore, when the result of multiplying the coefficient of “A+jB” is stored in the registers 11s and 11c, there is a limit to the number of bits, which causes rounding errors. This rounding error accumulates the more calculations are performed. As shown in the simulation and experimental results in the lower diagram of FIG. 3B, accumulating of the output digital data also increases the absolute value of data errors. It may be desirable to reset this error. Therefore, the data generation device 10 includes a reset counter 17 as shown in FIG. 1A.

The reset counter 17 is a circuit that starts counting from an initial value and outputs a reset signal R to the selectors 12s and 12c every time the count reaches a predetermined threshold value. When the selector 12s receives the reset signal R, the selector 12s temporarily switches the input and outputs a reset value (i.e., the initial value S) to the register 11s. When the selector 12c receives the reset signal R, the selector 12c temporarily switches the input and outputs a reset value (i.e., the initial value C) to the register 11c. As a result, the reset counter 17 and the selectors 12s and 12c function as a reset unit, so that the digital data generated by the generation unit S1 can be reset at periodic timing, and as a result, the error can be reset.

For example, as shown in FIG. 2, it may be preferable to provide a reset signal R1 every 360 degrees (i.e., 2π [rad]) of the fundamental period of the sine wave and cosine wave to clear the signals S and C to their initial values. In this case, the initial values are “S=0” and “C=1”. Furthermore, if the initial values S and C are set by periodically changing them, the reset signals R1 to R4 may be repeatedly applied every 90 degrees (i.e., π/4 [rad]).

In this case, it may be preferable to set the initial values S and C as (initial values of “S=0” and “C=1” @ reset signal R1), (initial values of “S=1” and “C=0” @ reset signal R2), (initial values of “S=0” and “C =−1” @ reset signal R3), (initial values of “S=−−1” and “C=0” @ reset signal R4). Here, the embodiment is described a feature in which the reset signal R1 or R1 to R4 is given periodically every 360 degrees or every 90 degrees by the function of the reset unit to clear the initial values S and C, alternatively, it is also possible to reset at any other arbitrary timing (for example, any timing such as 30 degrees, 10 degrees, 45 degrees or the like).

In the method described in the another conceivable technique in the Background Art section, the calculation error increases as the number of calculations increases, which is not preferable. Furthermore, an increase in the number of calculations is undesirable because it generates DC components. As in this embodiment, by using the reset counter 17 to reset the generated result of the generation unit S1 at any timing, the error components can be cleared, and sine waves (SIN) and cosine waves (COS) can be generated with as little DC components as possible.

### Feature of the Present Embodiment

As described above, according to this embodiment, the generation unit S1 generates the digital data by multiplying the stored values of the registers 11s and 11c by a predetermined coefficient of “(A+jB)” so as to rotate a unit vector on a two-dimensional complex plane for each predetermined step angle θ. Therefore, the digital data can be generated by calculation without using stored data, and the digital data constituting the frequencies of sine waves or cosine waves can be generated as accurately as possible.

### Second Embodiment

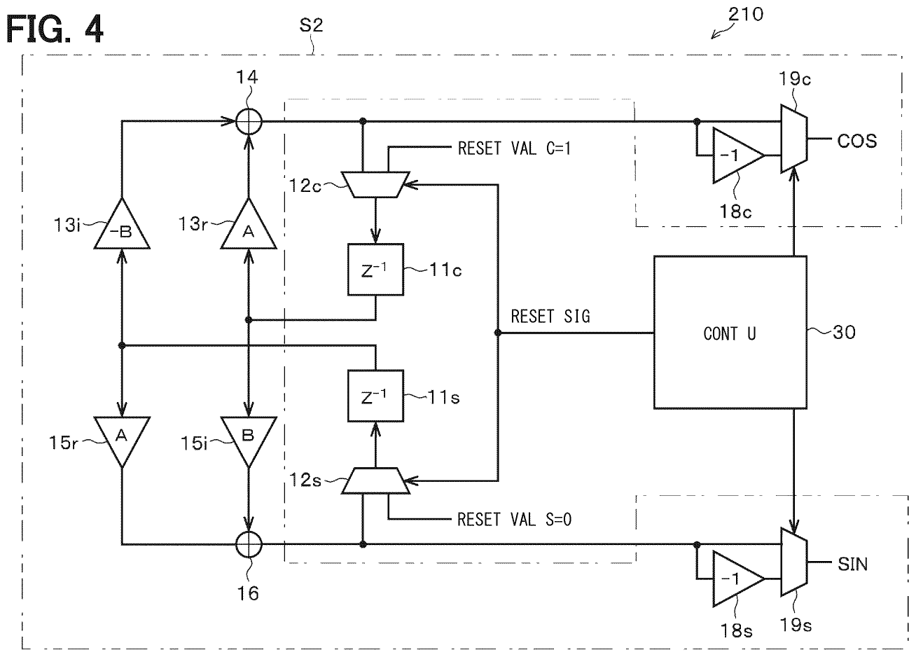

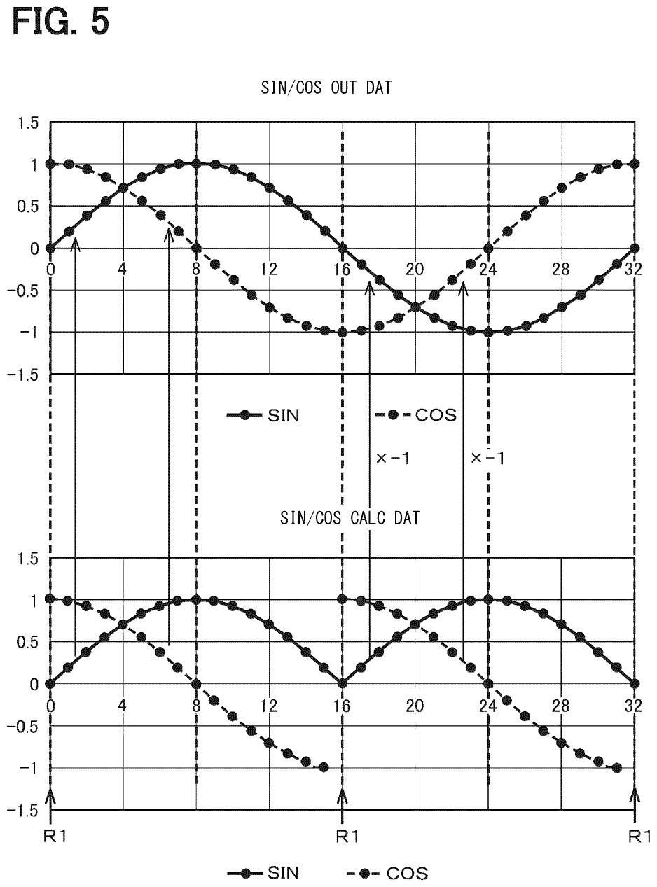

A second embodiment will be described with reference to FIGS. 4 and 5. The data generation device 210 includes the same configuration as the data generation device 10, as well as a control unit 30, sign inverters 18s and 18c, and the selectors 19s and 19c. The control unit 30 includes a digital control circuit and a counter, and generates reset signals R1 and R3 to be given to the selectors 12s and 12c, and also generates selection signals to be given to the selectors 19a and 19c.

The sign inverter 18s also receives the addition result from the adder 16, inverts the sign of the input digital data, and outputs the result to the selector 19s. The selector 19s selects whether to output the addition result of the adder 16 as is or to invert the sign based on a selection signal from the control unit 30, and outputs the result as sine wave (SIN) digital data.

The sign inverter 18c also receives the addition result from the adder 14, inverts the sign of the input digital data, and outputs the result to the selector 19c. The selector 19c selects whether to output the addition result of the adder 14 as is or to invert the sign based on a selection signal from the control unit 30, and outputs the result as cosine wave (COS) digital data.

The generation unit S2 of the second embodiment includes the same configuration as the generation unit S1 of the first embodiment, as well as sign inverters 18s and 18c and selectors 19s and 19c. The generation unit S2 may be defined to include the control unit 30. After the control unit 30 outputs a reset signal R1 to the selectors 12s and 12c to clear the output values of the selectors 12s and 12c to the initial values of “S=0” and “C=1”, the generation unit S2 generates digital data of the sine wave and cosine wave at calculation intervals T (T0, T1, T2 and the like in FIG. 3A) for the initial half of the basic period of the sine wave and cosine wave, as in the first embodiment. For a half (i.e., 180 degrees) of this initial fundamental period, the selectors 19s and 19c output the addition results of the adders 16 and 14 as they are.

After the generation unit S2 generates the digital data with half the original fundamental period, the control unit 30 outputs a reset signal R1 to the selectors 12s and 12c to clear the output values of the selectors 12s and 12c to the initial values of “S=0” and “C=1”. The control unit 30 also outputs the selection signals to the selectors 19s and 19c, and outputs the addition results of the adders 14 and 16, whose signs have been inverted by the sign inverters 18s and 18c, as the digital data of sine and cosine waves.

The generation unit S2 then regenerates the first half (i.e., 180 degrees) of the digital data that was originally generated, inverts the sign of the digital data, and outputs the data as the digital data of sine wave and cosine wave. As a result, when generating the digital data for the basic period of sine and cosine waves, the generation unit S2 repeats the generation of the initial first half (i.e., 180 degrees) of the digital data twice, and outputs the first half without inverting the sign and outputs the second half with inverted sign.

### Feature of the Present Embodiment

As described above, the generation unit S2 of the second embodiment generates the digital data of sine waves and cosine waves at a calculation interval T (i.e., T0, T1, T2 and the like) for the initial half of the fundamental period of the sine waves and cosine waves. The generation unit S2 then switches the signs of the digital data of the sine wave and cosine wave for the remaining half of the fundamental period of the sine wave and cosine wave, thereby generating the digital data of the sine wave and cosine wave during the fundamental period. This makes it possible to generate a waveform that minimizes DC components. In particular, the control unit 30 outputs a reset signal R1 to the selectors 12 s and 12 c, so that the initial values of “S=0” and “C=1” can be reset every half of the fundamental period, thereby reducing generation errors.

### Third Embodiment

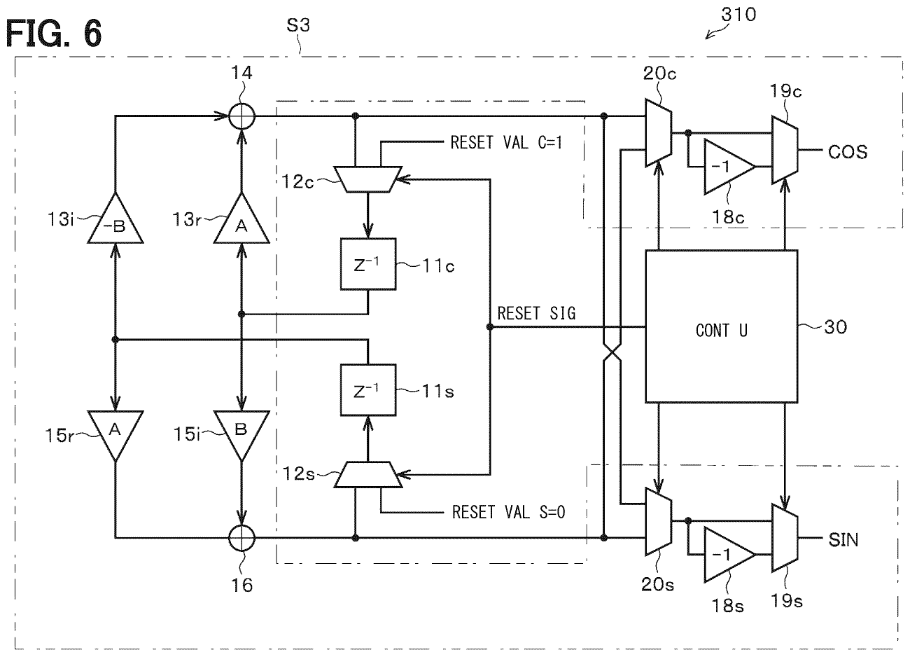

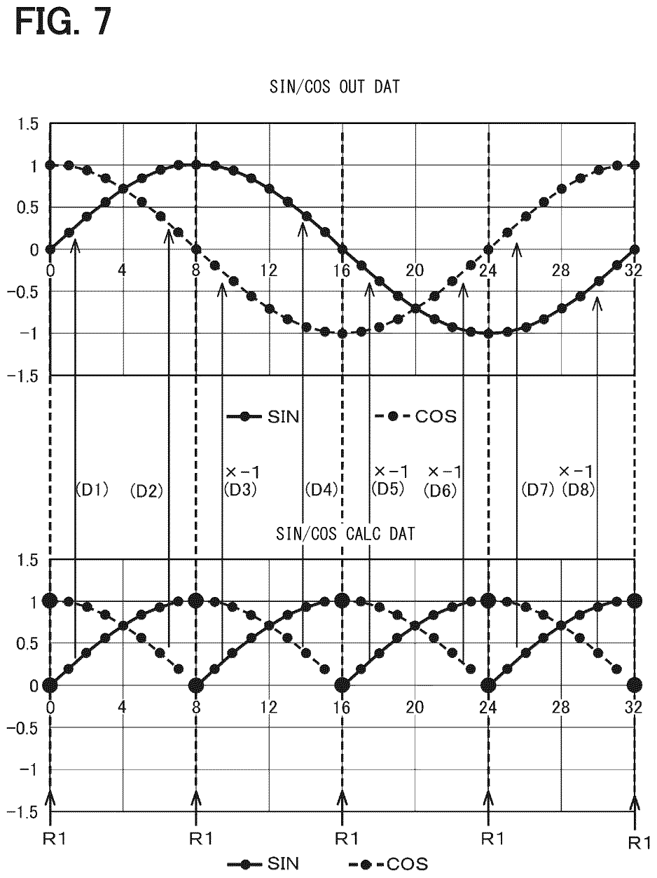

The following describes a third embodiment with reference to FIGS. 6 and 7. The data generation device 310 shown in FIG. 6 includes the same configuration as the data generation device 210 and also includes selectors 20s and 20c. The control unit 30 generates a reset signal R1 to be given to the selectors 12s and 12c, and also generates selection signals to be given to the selectors 19a, 19c, 20s, and 20c.

The selector 20s is provided to select the digital data for a sine wave, and selects one of the addition results of the adders 14 and 16 based on a selection signal input from the control unit 30, and outputs it to the selector 19s and the sign inverter 18s. When the sign inverter 18s receives the output digital data of the selector 20s, the sign inverter 18s inverts the sign of the input digital data and outputs it to the selector 19s. Based on a selection signal from the control unit 30, the selector 19s selects whether to output the output digital data of the selector 20s as is or to output the data after inverting the sign using the sign inverter 18s, and outputs the data as the sine wave (SIN) digital data.

The selector 20c is provided to select the digital data for a cosine wave, and selects one of the addition results of the adders 14 and 16 based on a selection signal input from the control unit 30, and outputs it to the selector 19c and the sign inverter 18c. The sign inverter 18c receives the output digital data of the selector 20c, inverts the sign of the input digital data, and outputs the data to the selector 19c. Based on a selection signal from the control unit 30, the selector 19c selects whether to output the output digital data of the selector 20c as it is or to output the data after inverting the sign using the sign inverter 18c, and outputs the data as the cosine wave (COS) digital data.

The generation unit S3 of the third embodiment includes selectors 20s and 20c in addition to the generation unit S2 of the second embodiment. After the control unit 30 outputs a reset signal R1 to the selectors 12s and 12c to clear the output values of the selectors 12s and 12c to the initial values of “S=0” and “C=1”, the generation unit S3 generates digital data of the sine wave and cosine wave at calculation intervals T (T0, T1, T2 and the like in FIG. 3A) for the initial 1/4 of the basic period of the sine wave and cosine wave, as in the first embodiment.

<From 0 degree to 90 degrees>

During this initial 1/4 (i.e., 90 degrees) of the fundamental period, based on the selection signal from the control unit 30, the selector 20s selects and outputs the addition result from the adder 16, and the selector 20c selects and outputs the addition result from the adder 14. The selectors 19s and 19c output the addition results of the adders 14 and 16 as they are. That is, the generation unit S3 outputs the addition results of the adders 16 and 14 as in the first embodiment as the digital data of sine waves and cosine waves, respectively, for the first quarter of the fundamental period (see (D1) and (D2) in FIG. 7).

After the generation unit S3 generates the digital data with 1/4 of the original fundamental period, the control unit 30 outputs a reset signal R1 to the selectors 12s and 12c to clear the output values of the selectors 12s and 12c to the initial values of “S=0” and “C=1”.

### <From 90 Degrees to 180 Degrees>

In addition, in the next quarter of the fundamental period, the control unit 30 outputs a selection signal to the selectors 20s and 20c to switch the data between the sine wave and the cosine wave. That is, the generation unit S3 outputs the addition result of the adder 14 to the selector 19s and the sign inverter 18s, and outputs the addition result of the adder 16 to the selector 19c and the sign inverter 18c. Furthermore, the control unit 30 outputs a selection signal to the selector 19c, and the addition result of the adder 16, the sign of which has been inverted by the sign inverter 18c, is output as the digital data of a cosine wave (see (D3) in FIG. 7). At the same time, the selector 19s outputs the output of the selector 20s, to which the addition result of the adder 14 has been input, as the sine wave digital data (see (D4) in FIG. 7).

After the generation unit S3 generates the digital data with 2/4 (i.e., 180 degrees) of the original fundamental period, the control unit 30 outputs a reset signal R1 to the selectors 12s and 12c to clear the output values of the selectors 12s and 12c to the initial values of “S=0” and “C=1”.

### <From 180 Degrees to 270 Degrees>

Furthermore, in the next quarter of the fundamental period, the control unit 30 outputs a selection signal to the selectors 20s and 20c to switch the data between the sine wave and the cosine wave from the previous state, and returns the data switching state to the original state. That is, the generation unit S3 outputs the addition result of the adder 16 to the selector 19s and the sign inverter 18s, and outputs the addition result of the adder 14 to the selector 19c and the sign inverter 18c. Furthermore, the selector 19c outputs the addition result of the adder 14, the sign of which has been inverted by the sign inverter 18c, as the digital data of a cosine wave (see (D5) in FIG. 7). At the same time, the control unit 30 outputs a selection signal from the previous state to the selector 19s, and outputs the addition result of the adder 16, the sign of which has been inverted by the sign inverter 18s, as the sine wave digital data (see (D6) in FIG. 7).

After the generation unit S3 generates the digital data with 3/4 (i.e., 270 degrees) of the original fundamental period, the control unit 30 outputs a reset signal R1 to the selectors 12s and 12c to clear the output values of the selectors 12s and 12c to the initial values of “S=0” and “C=1”.

### <From 270 Degrees to 360 Degrees>

In addition, in the next quarter of the fundamental period, the control unit 30 outputs a selection signal to the selectors 20s and 20c from the immediately previous state, thereby switching the data between the sine wave and the cosine wave. That is, the generation unit S3 outputs the addition result of the adder 14 to the selector 19s and the sign inverter 18s, and outputs the addition result of the adder 16 to the selector 19c and the sign inverter 18c. Furthermore, the selector 19c outputs the addition result of the adder 16 as it is as the digital data of a cosine wave (see (D7) in FIG. 7). At the same time, the selector 19s outputs the addition result of the adder 14, the sign of which has been inverted by the sign inverter 18s, as the sine wave digital data (see (D8) in FIG. 7).

After the generation unit S3 generates the digital data with 4/4 (i.e., 360 degrees) of the original fundamental period, the control unit 30 outputs a reset signal R1 to the selectors 12s and 12c to clear the output values of the selectors 12s and 12c to the initial values of “S=0” and “C=1”. Thereafter, the control is returned to the original state and the control is repeated (see (D1) in FIG. 7). The generation unit S3 can periodically generate the digital data of sine waves and cosine waves by repeating the same control.

### Feature of the Present Embodiment

As described above, the generation unit S3 of the third embodiment generates the digital data of sine waves and cosine waves at the calculation intervals T for the first quarter of the fundamental period of the sine waves and cosine waves. The generation unit S3 then switches the signs of the digital data of the sine wave and cosine wave and switches the data between the sine wave and the cosine wave for the remaining period of the basic period of the sine wave and cosine wave (i.e., for 3/4 of the basic period), thereby generating the digital data of the sine wave and cosine wave during the basic period. This makes it possible to generate a waveform that minimizes DC components. Furthermore, by the control unit 30 outputting a reset signal R1 every 1/4 of the fundamental period, the initial values of “S=0” and “C=1” can be reset every 1/4 of the fundamental period, thereby reducing generation errors.

### Fourth Embodiment

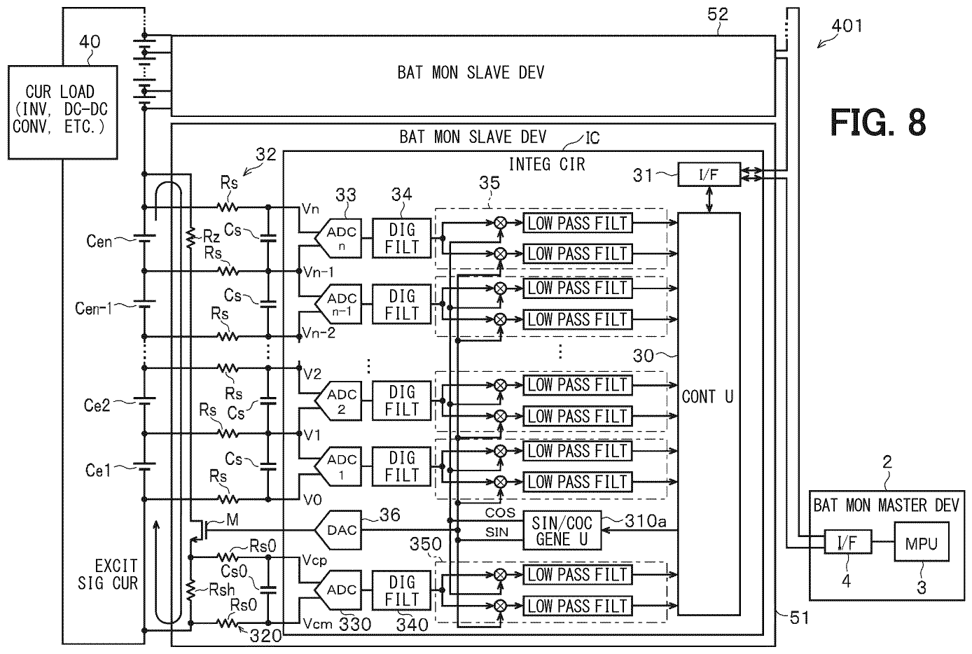

The fourth embodiment will be described with reference to FIGS. 8 to 10. FIG. 8 shows an example of the electrical configuration of a battery monitor system 401 in which the data generation device 310 shown in the third embodiment is incorporated as a SIN/COS generation unit 310a. Here, it should be noted that only the parts related to the features of this embodiment are extracted and described, and other block configurations are omitted. The SIN/COS generation unit 310a in FIG. 8 has the same configuration as the generation unit S3 of the data generation device 310, and therefore a description thereof will be omitted.

The battery monitor system 401 includes a battery monitor master device 2 and a plurality of battery monitor slave devices 51, 52, and the like. The battery monitor master device 2 includes an MPU 3 and an external interface 4, and is configured to be able to communicate with a plurality of battery monitor slave devices 51 and 52 via the external interface 4.

The battery monitor slave devices 51 and 52 each monitor the inter-terminal voltages of n unit cells Ce1, Ce2, Cen of the secondary battery connected in series. A series-connection circuit of unit cells Ce1, Ce2, Cen constitutes a battery pack, and the voltage of the series-connection circuit of the battery pack is applied to a current load 40.

The current load 40 is configured by an inverter or a DC-DC converter, and is connected in series to the unit cells Ce1, Ce2, Cen. The battery monitor slave device 51 includes RC filters 32 and 320, a FET_M, and an integrated circuit IC. The battery monitor slave device 51 or the integrated circuit IC is configured as a battery monitor device.

An RC filter 32 is connected to each of the unit cells Ce1, Ce2, Cen. The RC filter 32 is configured by connecting resistors Rs and capacitors Cs in a low-pass configuration as shown in FIG. 8, and inputting the voltages between the terminals of n capacitors Cs to an integrated circuit IC. The integrated circuit IC has a battery impedance measurement function using a lock-in amplifier. The battery monitor slave devices 51, 52 are configured to generate excitation signals to the unit cells Ce1, Ce2, Cen using the FET_M at a certain predetermined excitation frequency fexc, independent of the operation of the current load 40 as described above. When measuring the battery impedance, the integrated circuit IC measures the impedance at the excitation frequency fexc.

The integrated circuit IC includes n delta-sigma A/D converters 33, a digital filter 34, a lock-in amplifier 35, a control unit 30, and an external interface 31. The n delta-sigma A/D converters 33 input the inter-terminal voltages of the unit cells Ce1, Ce2, Cen via the RC filters 32 and perform A/D conversion. The digital filter 34 uses a CIC (Cascaded Integrator-Comb) filter, which reduces the sampling frequency and converts the signal into a multi-bit digital value.

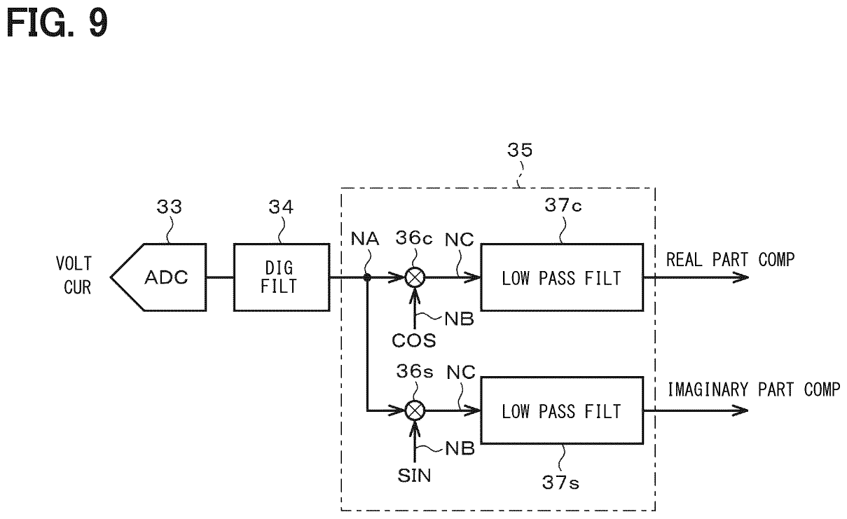

The lock-in amplifier 35 receives the output digital data of the digital filter 34. As shown in FIG. 9, the lock-in amplifier 35 includes multipliers 36c and 36s that respectively input IQ signals branched from the output of the digital filter 34, and LPFs 37c and 37s that respectively input the outputs of the multipliers 36c and 36s, cut high frequencies, and pass low frequencies.

The cosine wave (COS) and sine wave (SIN) signals generated by the SIN/COS generation unit 310a are input to the multipliers 36c and 36s, respectively, and the multipliers 36c and 36s perform the orthogonal conversion of the cosine wave (COS) and sine wave (SIN), respectively. When the outputs of the multipliers 36c and 36s are input to the LPFs 37c and 37s, the LPFs 37c and 37s cut the high frequencies to acquire the desired DC data, and output the real and imaginary parts (corresponding to complex signals) to the control unit 30, respectively. Therefore, the lock-in amplifier 35 converts the data generated by the SIN/COS generation unit 310a into a complex signal.

The control unit 30 can acquire information on the voltages between the terminals of the unit cells Ce1, Cen from the complex signal input from the lock-in amplifier 35. The external interface 31 is also connected to the external interface 4 of the battery monitor master device 2, enabling communication between the master device and the slave device. The battery monitor master device 2 communicates with each of the battery monitor slave devices 51, 52, thereby acquiring the information on the inter-terminal voltages of the unit cells Ce1, Ce2, Cen that are managed by each of the battery monitor slave devices 51, 52.

A set of an RC filter 320, a delta-sigma A/D converter 330, a digital filter 340, and a lock-in amplifier 350 is also provided for the shunt resistor Rsh. The inter-terminal voltage across the shunt resistor Rsh (i.e., Vcp-Vcm in FIG. 8) is input to the A/D converter 330 via an RC filter 320 including a resistor element Rs0 and a capacitor Cs0. The drain and source of the FET_M are connected in series to the shunt resistor Rsh, and further connected to a series-connection circuit of the unit cells Ce1, Ce2, Cen via a current limitation resistor Rz. The FET_M is an N-channel MOS transistor.

### <Impedance Measurement>

When measuring the impedance of the battery pack at the excitation frequency fexc of the current load 40, the MPU 3 of the battery monitor master device 2 sets the excitation frequency fexc of the SIN/COS generation unit 310a and transmits it to the target battery monitor slave device (e.g., 51). In addition, the MPU 3 transmits a measurement start command via the external interface 4 to cause the battery monitor slave device 51 to start operation, and the SIN/COS generation unit 310a to output an excitation signal with the excitation frequency fexc set above. A sine wave signal output from a SIN/COS generation unit 310a is applied to the gate of the FET_M through a DA converter 36.

When the FET_M is turned on and off, the A/D converter 330 detects a terminal voltage according to an excitation signal current flowing through the shunt resistor Rsh via the unit cells Ce1, Ce2, Cen, and performs the digital conversion. The digital filter 340 thins out the digital data, and the lock-in amplifier 350 performs the orthogonal conversion and cuts high frequencies, thereby making it possible to acquire a complex signal of the excitation signal current based on the direct current data. The integrated circuit IC can measure the impedance by the excitation signal current acquired together with the inter-terminal voltage of each of the unit cells Ce1, Ce2, Cen. The result of this impedance measurement is transmitted to the battery monitor master device 2, which is a higher-level device, via the external interfaces 31 and 4.

<Explanation of Frequency Spectrum and Technical Features of SIN/COS Generation unit 310a>

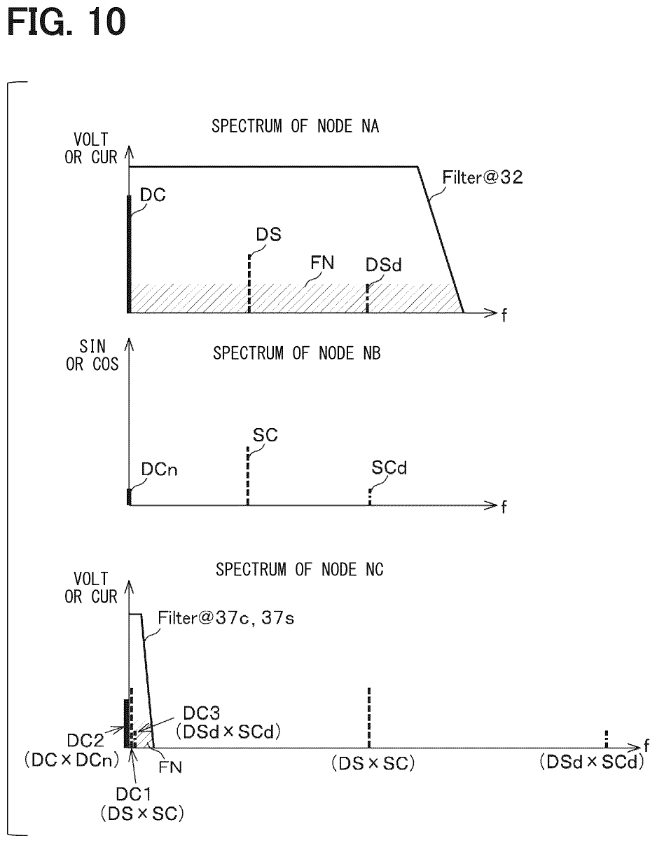

Next, the frequency spectrum distribution of the internal node of the lock-in amplifier 35 will be described with reference to FIGS. 9 and 10. As defined in FIG. 9, the output node of the digital filter 34 is defined as a node NA, the output node of the SIN/COS generation unit 310a is defined as a node NB, and the output node of the multiplier 36c (or 36s) is defined as a node NC.

In principle, the impedance of the battery is measured as described above, but components of the excitation frequency fexc and its harmonics are generated at the internal nodes of the lock-in amplifier 35. As shown in FIG. 10, at the node NA during the impedance measurement, a floor noise FN is superimposed at a low level on the current and voltage components of the excitation signal. As described above, the external RC filter 32 is used, so that the floor noise FN is cut in a predetermined high frequency band.

At the node NA, the excitation signal component DS of the output of the digital filter 34, its second harmonic component DSd, and the direct current component DC of the unit cells Ce1, Ce2, Cen appear to be superimposed on the frequency band of the floor noise FN. At the node NB, the main component SC of the SIN/COS generation unit 310a is generated, and its harmonic component SCd and the direct current error component DCn are also included in small amounts.

The multipliers 36c and 36s multiply the sine and cosine waves of the excitation frequency fexc of the excitation signal, thereby converting them into their sum and difference frequencies. Therefore, at the node NC, the DC component DC1 (shown as a dotted line in FIG. 10) acquired by multiplying the excitation signal component DS of the excitation frequency fexc at the node NA by the main component SC at the node NB can be acquired as the desired component.

In addition, at the node NC, a direct current error component DC2 (shown as a solid line in FIG. 10) resulting from the multiplication of the direct current component DC and the direct current error component DCn is also extracted. Furthermore, a direct current error component DC3 (shown as a dashed line in FIG. 10) acquired by multiplying the second harmonic component DSd of the excitation signal of the excitation frequency fexc by the harmonic component SCd of the SIN/COS generation unit 310a is also extracted as an undesired component.

The LPFs 37c and 37s provided on a downstream side of the node NC can extract only low frequency components by cutting out predetermined high frequency components, thereby significantly reducing the floor noise FL, but cannot cut out the direct current error components DC2 and DC3.

In this case, if the SIN/COS generation unit 310a generates a large direct current error component DCn or a large harmonic component SCd at the node NB, which have the same frequency as the components generated at the node NA, this may result in the direct current error components DC2 and DC3 being generated to a non-negligible extent, which is undesirable. In particular, in order for the integrated circuit IC to accurately measure the direct current component DC1 of the unit cells Ce1, Ce2, Cen of the battery, it may be desirable to reduce the direct current error components DC2 and DC3 as much as possible.

### Feature of the Present Embodiment

In this embodiment, the SIN/COS generation unit 310a is configured as shown in the data generation device 310 described in the third embodiment, so that the digital data of sine waves and cosine waves with a fundamental period can be generated at the node NB while minimizing the generation of the direct current error components DCn and harmonic components SCd. Therefore, only the desired main component SC can be generated while suppressing the occurrence of the direct current error component DCn and harmonic component SCd at the node NB, and as a result, the direct current error components DC2 and DC3 appearing at the node NC can be reduced. This allows the direct current component DC1 of the unit cells Ce1, Ce2, Cen of the battery to be measured as accurately as possible.

### Fifth Embodiment

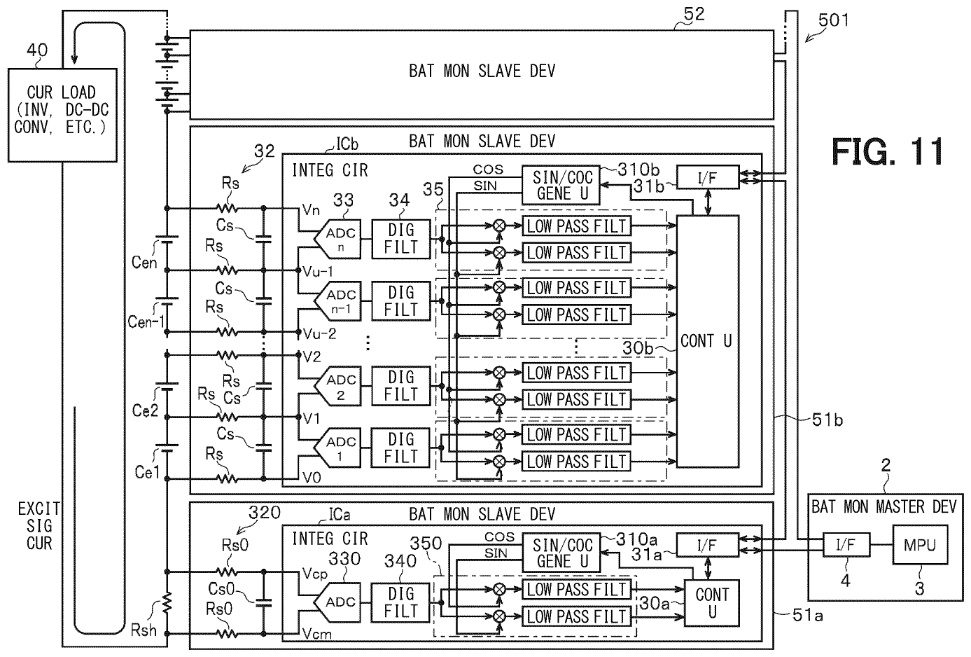

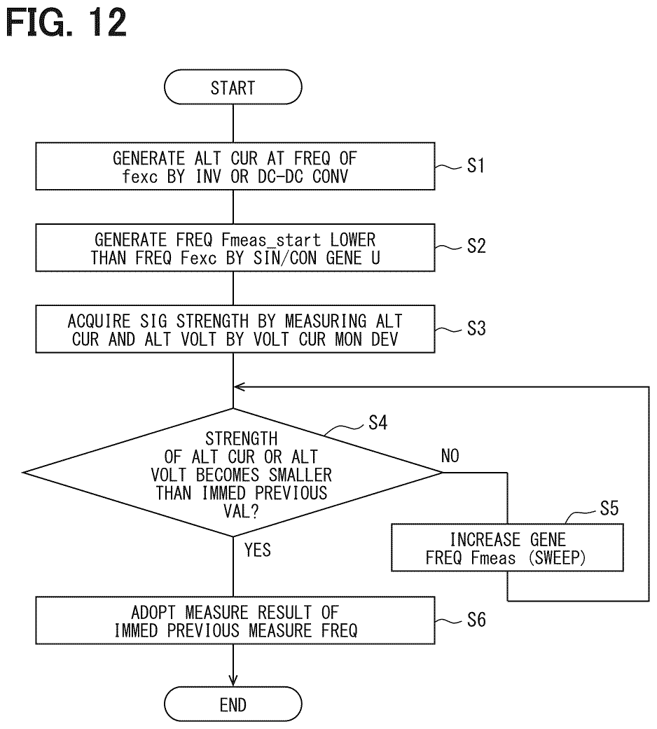

The fifth embodiment will be described with reference to FIGS. 11 and 12. FIG. 11 shows an example of the electrical configuration of a battery monitor system 501 in which the data generation device 310 shown in the third embodiment is incorporated as the SIN/COS generation units 310a and 310b.

The SIN/COS generation units 310a and 310b shown in FIG. 11 have the same configuration as the generation unit S3 of the data generation device 310, and the control units 30a and 30b have the same configuration as the control unit 30, so their description will be omitted. Here, it should be noted that only the parts related to the features of this embodiment are extracted and described, and other block configurations are omitted.

The battery monitor system 501 includes a battery monitor master device 2 and a plurality of battery monitor slave devices 51a, 51b, 52, and the like. The fifth embodiment differs from the fourth embodiment in that the function of the battery monitor slave device 51 of the fourth embodiment is divided into two battery monitor slave devices 51a and 51b.

The battery monitor slave devices 51a, 51b, 52, and the like are used in a system in which an external current load 40 is excited at an excitation frequency fexc. The battery monitor slave device 51a is provided for the shunt resistor Rsh. The battery monitor slave device 51b is a device that monitors the inter-terminal voltages of n unit cells Ce1, Ce2, Cen of a secondary battery connected in series. A series-connection circuit of unit cells Ce1, Ce2, Cen constitutes a battery pack, and the voltage of the series-connection circuit is applied to a current load 40.

The current load 40 is configured by an inverter or a DC-DC converter, and operates at a relatively low excitation frequency fexc (for example, about 0.1 Hz to 1 kHz). The battery monitor slave device 51a includes an RC filter 320 and an integrated circuit ICa. The battery monitor slave device 51b includes an RC filter 32 and an integrated circuit ICb. The battery monitor slave devices 51a and 51b or the integrated circuits ICa and ICb are configured to correspond to battery monitor devices.

The integrated circuits ICa and ICb cooperate with each other to provide a battery impedance measurement function using a lock-in amplifier. When measuring the battery impedance, the integrated circuit ICa measures the excitation signal current at the excitation frequency fexc of the current load 40 through the shunt resistor Rsh. The integrated circuit ICb also measures the inter-terminal voltages across the terminals of the unit cells Ce1, Ce2, Cen at the excitation frequency fexc of the current load 40, and calculates the impedance of the battery from these measurement results.

That is, in the fourth embodiment, the impedance of the battery is measured by intentionally passing an excitation signal current of the excitation frequency fexc from the SIN/COS generation unit 310a through the unit cells Ce1, Ce2, Cen, but the fifth embodiment is different in that the impedance of the battery is measured when an excitation signal current of the excitation frequency fexc to be passed through the current load 40 flows through the unit cells Ce1, Ce2, Cen.

The integrated circuit ICa includes a delta-sigma A/D converter 330, a digital filter 340, a lock-in amplifier 350, a control unit 30a, and an external interface 31a. The integrated circuit ICb includes n delta-sigma A/D converters 33, a digital filter 34, a lock-in amplifier 35, a control unit 30b, and an external interface 31b. The delta-sigma A/D converters 33 and 330, the digital filters 34 and 340, and the lock-in amplifiers 35 and 350 have the same configurations as those in the fourth embodiment, and therefore a description thereof will be omitted. Furthermore, the configurations of the control units 30a and 30b and the external interfaces 31a and 31b have the same configuration as those of the control unit 30 and the external interface 31 of the fourth embodiment, and therefore a description thereof will be omitted.

As a result, by communicating with each battery monitor slave device 51a, 51b, 52, and the like, the battery monitor master device 2 can acquire the information on the excitation signal current handled by each battery monitor slave device 51a, 51b, and the information on the inter-terminal voltage of the unit cells Ce1, Ce2, Cen.

<Explanation of Technical Features of this Embodiment>

It is difficult to strictly match the excitation frequency fexc of the inverter and DC-DC converter that constitute the current load 40 and the measurement frequency fmeas of the sine and cosine waves of the SIN/COS generation units 310a and 310b of the integrated circuits ICa and ICb that constitute the battery monitor system 501 from the default. If the excitation frequency fexc and the measurement frequency fmeas do not match, it becomes difficult for the lock-in amplifiers 35 and 350 to detect the direct current component DC1.

Therefore, in this embodiment, the measurement frequency fmeas of the excitation signal of the SIN/COS generation units 310a and 310b is swept to search for the excitation frequency fexc of the current load 40, and a measurement frequency fmeas that matches or is close to the excitation frequency fexc is searched for. The operation at this time will be described with reference to the flowchart of FIG. 12.

As shown in FIG. 12, the battery monitor master device 2 of the battery monitor system 501 first operates the inverter or the DC-DC converter that constitutes the current load 40 in S1 to excite an alternating current of the excitation frequency fexc. Then, an excitation signal current flows through the unit cells Ce1, Ce2, Cen and the shunt resistor Rsh.

Next, in S2, the battery monitor slave devices 51a and 51b generate sine waves and cosine waves at a start measurement frequency fmeas_start that is lower than the excitation frequency fexc using the SIN/COS generation units 310a and 310b. Then, in S3, the control unit 30b measures the alternating voltages associated with the unit cells Ce1, Ce2, Cen, and the control unit 30a measures the alternating current based on the shunt resistance Rsh, thereby determining the signal strength. Here, the control units 30a and 30b monitor the strength of the real and imaginary parts (i.e., a complex signal) acquired by converting the inter-terminal voltages and currents flowing through the unit cells Ce1, Ce2, Cen using the lock-in amplifiers 35 and 350 based on the signals excited by the current load 40 of the battery monitor system 501.

The control units 30a and 30b of the battery monitor slave devices 51a and 51b transmit the information on the measurement results of the signal strength to the MPU 3 of the battery monitor master device 2. The MPU 3 sequentially stores the information on the signal strength of the alternating voltage and alternating current in the internal memory, and determines whether or not these monitored strength have become smaller than the immediately previous values (at S4).

When the MPU 3 determines in S4 that the monitored strength is equal to or larger than the immediately previous value (“NO” in S4), the MPU 3 commands the SIN/COS generation units 310a and 310b to increase the measurement frequency fmeas in S5. Then, the SIN/COS generation units 310a and 310b change the measurement frequency fmeas and output sine waves and cosine waves to the lock-in amplifiers 35 and 350. Thereafter, the process of S4 and S5 is repeatedly executed and the process stands by until the monitor signal strength becomes smaller than the immediately previous value (“YES” in S4).

In other words, the battery monitor slave devices 51a, 51b use the SIN/COS generation units 310a, 310b to sweep the measurement frequency fmeas of sine waves and cosine waves, while the control units 30a, 30b monitor the strength of the reception signals of the real and imaginary parts (i.e., the complex signals) acquired by converting the signals excited by the battery monitor system 501 using the lock-in amplifiers 35, 350 (to function as monitor units). Then, the process of S4 and S5 is repeatedly executed and the process stands by until the monitor signal strength becomes smaller than the immediately previous value (“YES” in S4). This allows the excitation frequency fexc to be searched for based on the strength of the monitored signal.

If the monitor signal strength becomes smaller than the immediately previous value (“YES” in S4), the MPU 3 adopts the measurement result of the previous measurement frequency fmeas and commands the measurement result of the previous measurement frequency fmeas as the measurement frequency fmeas of the SIN/COS generation units 310a and 310b, and then, the SIN/COS generation units 310a and 310b use the measurement result of the previous measurement frequency fmeas. This allows the measurement frequency fmeas that provides the highest monitor signal strength to be set in the SIN/COS generation units 310a and 310b. As a result, the lock-in amplifiers 35 and 350 can easily detect the desired direct current component DC1.

By finely setting the coefficient A of the real part and the coefficient B of the imaginary part shown in FIG. 1 for each measurement frequency fmeas (i.e., f1, f2, and the like), the frequency settings of the SIN/COS generation units 310a and 310b can be changed finely. Therefore, as shown in this embodiment, even if the measurement frequency fmeas is swept at small frequency intervals, it can be flexibly handled.

Here, the features have explained in an embodiment in which the MPU 3 of the battery monitor master device 2 functions as a main body to command the measurement frequency fmeas, but it may be not limited to this feature, and either the control unit 30a or 30b of the battery monitor slave devices 51a, 51b may function as a main body to command and sweep the measurement frequency fmeas with each other.

### Other Embodiments

The present embodiments are not limited to the above-described embodiment, and the following modifications or expansions are possible. In the above-described embodiments, the data generation devices 10, 210, 310 have been described as generating predetermined wave data of sine waves (SIN) and cosine waves (COS) periodically over one or more periods, but it may not be limited to this feature and may be applied to a feature that outputs data of either sine waves or cosine waves, or to a feature that generates data for at least a portion of one period of these sine waves or cosine waves, for example, 30 degrees, 60 degrees, 90 degrees, 180 degrees, or 270 degrees.

Although the embodiment has been described in which the unit vector is rotated left on a two-dimensional complex plane for each predetermined step angle, it may not be limited to this feature and may be applied to a form in which the unit vector is rotated right. When rotating left, the coefficient B is set to a positive value and the coefficient-B is set to a negative value, but when rotating right, the coefficient B is set to a negative value and the coefficient-B is set to a positive value. In this manner, the digital data of a predetermined wave can also be generated.

The data generation devices 10, 210, 310 and methods described in the embodiments may be implemented by a special purpose computer provided by configuring a processor and a memory programmed to perform one or more functions embodied in a computer program. Alternatively, the data generation devices 10, 210, 310 and methods described in the embodiments may be implemented by a special purpose computer provided by configuring a processor with one or more dedicated hardware logic circuits.

Alternatively, the data generation devices 10, 210, 310 and methods described herein may be implemented by one or more special-purpose computers configured by combining a processor and a memory programmed to perform one or more functions with a processor configured by one or more hardware logic circuits. The computer program may be stored, as instructions to be executed by a computer, in a tangible non-transitory computer-readable medium.

Namely, the means and/or the functions which are provided by the processor and the like may be provided by software stored in tangible memory devices and computers for executing them, only software, only hardware, or a combination thereof. For example, some or all of the functions provided by the authentication processor may be realized as hardware. A mode in which a certain function is realized as hardware includes a mode in which one or more ICs are used.

In addition to the contents set forth in the features, the present embodiments also include the following features.

Feature 1: A data generation device generates digital data of at least a part of a sine wave (SIN) or a cosine wave (COS) (hereinafter referred to as a predetermined wave). The data generation device includes: a storage unit to which an initial value is given; and a generation unit that generates the digital data by multiplying a stored value of the storage unit by a predetermined coefficient at a predetermined calculation interval that is shorter than a fundamental period of the predetermined wave. The predetermined coefficient is preliminarily determined so as to rotate a unit vector on a two-dimensional complex plane for each predetermined step angle of the predetermined wave.

Feature 2: The data generation device according to feature 1, further includes: a reset unit that resets an error by resetting a generated result of the generation unit at certain timing.

Feature 3: In the data generation device according to feature 1 or 2, the generation unit generates the sine wave and the cosine wave as the predetermined wave. The generation unit repeatedly generates the digital data of the sine wave and the cosine wave at the predetermined calculation interval for an initial half of the fundamental period of the sine wave and the cosine wave. The generation unit generates the digital data of the sine wave and the cosine wave during the fundamental period by switching a sign of the digital data of the sine wave and the cosine wave during a remaining period of the fundamental period of the sine wave and the cosine wave.

Feature 4: In the data generation device according to feature 1 or 2, the generation unit generates the sine wave and the cosine wave as the predetermined wave. The generation unit repeatedly generates the digital data of the sine wave and the cosine wave at the predetermined calculation interval for an initial quarter of the fundamental period of the sine wave and the cosine wave. The generation unit generates the digital data of the sine wave and the cosine wave during the fundamental period by switching a sign of the digital data of the sine wave and the cosine wave and switching the digital data of the sine wave and the cosine wave during a remaining period of the fundamental period of the sine wave and the cosine wave.

Feature 5: A battery monitor device includes: the data generation device according to any one of features 1 to 4; and a lock-in amplifier that uses the digital data generated by the data generation device to convert the digital data into a complex signal.

Feature 6: In the battery monitor device according to feature 5, the battery monitor device is used in a system in which an external load is excited at an excitation frequency. The data generation device is configured to sweep a measurement frequency of the sine wave and the cosine wave. The battery monitor device further includes: a monitor unit that monitors a strength of the complex signal acquired by converting a signal excited in the system using the lock-in amplifier. The excitation frequency is searched for based on a monitored strength of the complex signal.

Feature 7: A data generation method is used for generating digital data of at least a part of a sine wave (SIN) or a cosine wave (COS) (hereinafter referred to as a predetermined wave). The data generation device includes a storage unit that stores an initial value. A generation unit generates the digital data by multiplying a stored value of the storage unit by a predetermined coefficient at a predetermined calculation interval that is shorter than a fundamental period of the predetermined wave. The predetermined coefficient is preliminarily determined so as to rotate a unit vector on a two-dimensional complex plane for each predetermined step angle of the predetermined wave.

Feature 8: A data generation program is used for generating digital data of least a part of a sine wave (SIN) or a cosine wave (COS) (hereinafter referred to as a predetermined wave) using a data generation device. The data generation device includes a storage unit that stores an initial value. The data generation program causes the data generation device to execute: a step of storing the initial value in the storage unit; and a step of generating the digital data using a generation unit that multiplies a stored value of the storage unit by a predetermined coefficient at a predetermined calculation interval that is shorter than a fundamental period of the predetermined wave. The predetermined coefficient is preliminarily determined so as to rotate a unit vector on a two-dimensional complex plane for each predetermined step angle of the predetermined wave.

In the drawings, reference numerals 10, 210, and 310 indicate data generation devices, reference numerals 11s and 11c indicate registers (corresponding to storage units), reference numerals 310a and 310b indicate SIN/COS generation units (corresponding to data generation devices), reference numerals S1, S2, and S3 indicate generation units, reference signs IC, ICa, and ICb indicate integrated circuits (corresponding to battery monitor devices), and reference numerals 51, 51a, 51b, and 52 indicate battery monitor slave devices (corresponding to battery monitor devices).

Although the present disclosure has been described in accordance with the foregoing embodiments, it is understood that the present disclosure is not limited to the above embodiments or structures. The present disclosure includes various modifications or deformations within an equivalent range. In addition, while the various combinations and configurations, which are preferred, other combinations and configurations, including more, less or only a single element, are also within the spirit and scope of the present disclosure.

It is noted that a flowchart or the processing of the flowchart in the present application includes sections (also referred to as steps), each of which is represented, for instance, as S1. Further, each section can be divided into several sub-sections while several sections can be combined into a single section. Furthermore, each of thus configured sections can be also referred to as a device, module, or means.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A data generation device for generating digital data of at least a part of a sine wave or a cosine wave referred to as a predetermined wave, the data generation device comprising:
a storage to which an initial value is given; and
at least one processor with a memory, wherein:
the at least one processor with the memory is configured to cause the data generation device to execute: generating the digital data by multiplying a stored value of the storage by a predetermined coefficient at a predetermined calculation interval that is shorter than a fundamental period of the predetermined wave; and
the predetermined coefficient is preliminarily determined so as to rotate a unit vector on a two-dimensional complex plane for each predetermined step angle of the predetermined wave.

2. The data generation device according to claim 1, wherein:
the at least one processor with the memory is configured to cause the data generation device to further execute: resetting an error by resetting a generated result of the generating of the digital data at certain timing.

3. The data generation device according to claim 1, wherein:
the at least one processor with the memory is configured to cause the data generation device to execute: generating the sine wave and the cosine wave as the predetermined wave;
the at least one processor with the memory is configured to cause the data generation device to execute: repeatedly generating the digital data of the sine wave and the cosine wave at the predetermined calculation interval for an initial half of the fundamental period of the sine wave and the cosine wave; and
the at least one processor with the memory is configured to cause the data generation device to execute: generating the digital data of the sine wave and the cosine wave during the fundamental period by switching a sign of the digital data of the sine wave and the cosine wave during a remaining period of the fundamental period of the sine wave and the cosine wave.

4. The data generation device according to claim 1, wherein:
the at least one processor with the memory is configured to cause the data generation device to execute: generating the sine wave and the cosine wave as the predetermined wave;
the at least one processor with the memory is configured to cause the data generation device to execute: repeatedly generating the digital data of the sine wave and the cosine wave at the predetermined calculation interval for an initial quarter of the fundamental period of the sine wave and the cosine wave; and
the at least one processor with the memory is configured to cause the data generation device to execute: generating the digital data of the sine wave and the cosine wave during the fundamental period by switching a sign of the digital data of the sine wave and the cosine wave and switching the digital data of the sine wave and the cosine wave during a remaining period of the fundamental period of the sine wave and the cosine wave.

5. The data generation device according to claim 1, wherein:
the at least one processor with the memory is configured to cause the data generation device to execute: generating the digital data by multiplying a stored value of the storage by a predetermined coefficient at a predetermined calculation interval that is shorter than a fundamental period of the predetermined wave as a function of a generation unit.

6. The data generation device according to claim 2, wherein:
the at least one processor with the memory is configured to cause the data generation device to further execute: resetting an error by resetting a generated result of the generation unit at certain timing as a function of a reset unit.

7. The data generation device according to claim 1, wherein:
the digital data generated by the data generation device is converted into a complex signal;
the complex signal is input into a control unit to acquire information about an inter-terminal voltage of each of a plurality of unit cells which are connected in series to provide a battery pack;
a voltage of the battery pack is applied to a current load to operate the current load; and
the inter-terminal voltage of each of the plurality of unit cells is monitored to operate the battery pack properly.

8. A battery monitor device comprising:
the data generation device according to claim 1; and
a lock-in amplifier that uses the digital data generated by the data generation device to convert the digital data into a complex signal.

9. The battery monitor device according to claim 8, wherein:
the battery monitor device is used in a system in which an external load is excited at an excitation frequency; and
the data generation device is configured to sweep a measurement frequency of the sine wave and the cosine wave,
the battery monitor device further comprising:
a monitor unit that monitors a strength of the complex signal acquired by converting a signal excited in the system using the lock-in amplifier, wherein:
the excitation frequency is searched for based on a monitored strength of the complex signal.

10. A data generation method for generating digital data of at least a part of a sine wave or a cosine wave referred to as a predetermined wave, the data generation method comprising:
storing an initial value in a storage; and
generating the digital data using a generation unit by multiplying a stored value of the storage by a predetermined coefficient at a predetermined calculation interval that is shorter than a fundamental period of the predetermined wave, wherein:
the predetermined coefficient is preliminarily determined so as to rotate a unit vector on a two-dimensional complex plane for each predetermined step angle of the predetermined wave.

11. The data generation method according to claim 10, wherein:
the digital data is converted into a complex signal;
the complex signal is input into a control unit to acquire information about an inter-terminal voltage of each of a plurality of unit cells which are connected in series to provide a battery pack;
a voltage of the battery pack is applied to a current load to operate the current load; and
the inter-terminal voltage of each of the plurality of unit cells is monitored to operate the battery pack properly.

12. A non-transitory computer readable storage medium comprising instructions being executed by a computer, the instructions including a computer-implemented method for generating digital data of at least a part of a sine wave or a cosine wave referred to as a predetermined wave using a data generation device, the data generation device including a storage that stores an initial value, the instructions including:
a step of storing the initial value in the storage; and
a step of generating the digital data using a generation unit by multiplying a stored value of the storage by a predetermined coefficient at a predetermined calculation interval that is shorter than a fundamental period of the predetermined wave, wherein:
the predetermined coefficient is preliminarily determined so as to rotate a unit vector on a two-dimensional complex plane for each predetermined step angle of the predetermined wave.

13. The non-transitory computer readable storage medium according to claim 12, wherein:
the digital data is converted into a complex signal;
the complex signal is input into a control unit to acquire information about an inter-terminal voltage of each of a plurality of unit cells which are connected in series to provide a battery pack;
a voltage of the battery pack is applied to a current load to operate the current load; and
the inter-terminal voltage of each of the plurality of unit cells is monitored to operate the battery pack properly.
